(19) United States
(12) Patent Application Publication
(10) Pub. No.: US 2011/0120525 A1
(43) Pub. Date: May 26, 2011

(54) MOLDING PROCESSES FOR LIGHT CONCENTRATING ARTICLES THAT ARE USED IN SOLAR CELL MODULES

(75) Inventors: Alison Margaret Anne Bennett, Wilmington, DE (US); Philip L. Boydell, Challex (FR); Roger Harquail French, Cleveland Heights, OH (US); Karlheinz Hausmann, Auvernier (CH); Richard Allen Hayes, Beaumont, TX (US); Steven C. Pesek, Orange, TX (US); Jose Manuel Rodriguez-Parada, Hockessin, DE (US); Jacques Roulin, Vesenaz (CH); Charles Anthony Smith, Vienna, WV (US)

(73) Assignee: E. I. Du Pont De Nemours and Company, Wilmington, DE (US)

(21) Appl. No.: 12/953,974

(22) Filed: Nov. 24, 2010

Related U.S. Application Data
(60) Provisional application No. 61/264,456, filed on Nov. 25, 2009.

(51) Int. Cl. H01L 31/055; H01L 31/052

(52) U.S. Cl. 136/246; 264/1.1

(57) ABSTRACT

Light concentrating articles capable of concentrating about 1.02 to about 2000 sun equivalents of solar energy onto a solar cell comprise a thermoplastic composition, preferably an ionomer composition. The light concentrating articles may be made by a variety of processes, which are provided herein, such as for example an injection molding process, an injection overmolding process, an extrusion process, a cast film or sheet process, a blown film or sheet process, a vacuum forming process, a compression molding process, a transfer molding process, or a profile extrusion process. Secondary forming processes, such as bending, stamping, embossing, machining, laminating, adhering, metallizing, and the like may also be used in forming the light concentrating articles.

### FIELD OF THE INVENTION

The invention relates to concentrator solar cell modules comprising at least one light concentrating article. The light concentrating article(s) comprise or are produced from a thermoplastic composition, preferably an ionomeric composition. Several methods of manufacturing the light concentrating articles are provided herein.

### BACKGROUND OF THE INVENTION

Several patents and publications are cited in this description in order to more fully describe the state of the art to which this invention pertains. The entire disclosure of each of these patents and publications is incorporated by reference herein.

The use of solar cells, which produce electricity from visible light, is rapidly expanding because of a need for renewable and sustainable energy resources. Solar cells can be categorized into two types, bulk or wafer-based solar cells and thin film solar cells. A comprehensive description of solar cells and photovoltaic devices appears in the Handbook of Photovoltaic Science and Engineering by Antonio Luque and Steven Hegedus, published by John Wiley and Sons (2003, Hoboken, N.J.).

In particular, light concentrating solar cell modules improve the efficiency of typical solar cell modules by increasing the amount of light that is gathered and cast on the solar cell. These concentrator solar cell modules include a light concentrating article, such as a reflective or refractive optical system, to capture the sunlight shining on a given area and cast it onto solar cell(s) that have a smaller surface area.

Increasing the amount of light that is cast on each solar cell increases the amount of electricity that the solar cell produces. For example, a concentrator solar cell module with a relatively low efficiency is capable of providing a solar concentration factor of about 0.01 to 10 suns, while a concentrator solar cell module with a relatively high efficiency can provide a solar concentration factor of about 200 suns or higher.

Moreover, light concentrating articles are generally less costly than solar cells, which typically are made of silicon or of highly efficient III-V materials such as GaAs. Therefore, the use of concentrator solar cell modules also provides an economic efficiency.

Several light concentrating articles and concentrator solar cell modules have been developed and described in the literature including, without limitation, the following. First, encapsulant layers with embossed grooves to redirect light into solar cells are described in U.S. Pat. Nos. 5,110,370; 5,228,926; and 5,554,229. Converging lenses are described in U.S. Pat. Nos. 4,053,327; 4,188,238; 4,253,880; 4,331,829; 4,379,202; 4,836,861; 5,096,505; 5,116,427; 5,167,724; 5,123,968; 6,111,190; 6,700,054; in U.S. Patent Appln. Publn. No. 2008/0087323; in European Patent No. 0 581 889; and in Intl. Patent Appln. Publn. No. WO2007/044384. Concentrating coverglasses are described in U.S. Pat. Nos. 5,959,787; 6,091,020; 2006/0283497; and in European Patent No. 0 255 900. Fresnel lenses are described in U.S. Pat. Nos. 3,125,091; 4,545,366; 4,848,319; 5,118,361; 5,217,539; 5,496,414; 5,498,297; 5,578,139; in U.S. Patent Appln. Publn. Nos. 2003/0201007 and 2004/0112424; in European Patent No. 1 892 771; and in Intl. Patent Appln. Publn. Nos. WO 2006/120475 and WO 2007/041018. In addition, U.S. Pat. Nos. 5,344,497; 5,505,789; and 6,075,200 describe the use of linear arched Fresnel line focussed lenses in concentrator solar cell modules. U.S. Pat. No. 4,069,812 and U.S. Pat. No. 6,031,179 describe the use of curved prismatic Fresnel-type lenses in concentrator solar cell modules. U.S. Patent Appln. Publn. No. 2003/0075212 describes the use of a Fresnel-type refractive concentrator in series with parabolic reflector concentrators. U.S. Patent Appln. Publn. No. 2005/0081908 describes the use of concentrator lenslets for a miniature photovoltaic device array. Finally, integral concentrator solar cell modules incorporating converging lenses are described in U.S. Patent Appln. Publn. Nos. 2005/0081909; 2006/0283495; 2007/0056626; 2008/0053515; and 2007/0095386; and in Intl. Patent Appln. Publn. No. WO 2007/093422.

The light concentrating articles used in the concentrator solar cell modules are often made of glass or plastics, such as polycarbonates and acrylics such as poly(methyl methacrylate). For example, the use of acrylics, polystyrenes, polycarbonates, or methacrylate styrene copolymers as materials for Fresnel lenses is described in U.S. Pat. Nos. 4,069,812; 4,188,238; 4,545,366; and 5,498,297, and the use of acrylics as materials for converging lenses is described in U.S. Pat. No. 6,700,054. A comprehensive description of these optical plastics and their properties appears in the “Handbook of Optical Materials” by M. Weber, published by the CRC Press (Boca Raton, 2002).

It is noted, however, that glass and some polymers cannot easily be formed into light concentrating articles through low cost melt processing. For example, most low-shrinkage optical grade silicones are two-component reactive thermoset systems. Usually, two liquids have to be mixed and poured into the desired mold. After degassing, the mold is heated to finish crosslinking the material. Moreover, silicone monomers and additives affect adhesion negatively and can contaminate processing equipment.

Accordingly, there remains a need to develop new methods for manufacturing the light concentrating articles that are included in concentrator solar cell modules. Desirably, the light concentrating articles comprise thermoplastic materials and the new methods are melt processing methods.

### SUMMARY OF THE INVENTION

Provided herein are processes for manufacturing light concentrating articles for use in concentrator solar cell modules. The light concentrating articles, which are capable of concentrating about 1.02 to about 2000 sun equivalents of solar energy onto a solar cell, comprise or are made from thermoplastic compositions, preferably ionomer compositions. The processes provided include an injection molding process, an injection overmolding process, an extrusion process, a cast film or sheet process, a blown film or sheet process, a vacuum forming process, a compression molding process, a transfer molding process, or a profile extrusion process. Secondary forming processes, such as bending, stamping, embossing, machining, laminating, adhering, metallizing, and the like may also be used in forming the light concentrating articles. It may be necessary or desirable to use two or more of the processes or secondary processes to form the light concentrating article.

### DETAILED DESCRIPTION OF THE INVENTION

The following definitions apply to the terms as used throughout this specification, unless otherwise limited in specific instances.

The technical and scientific terms used herein have the meanings that are commonly understood by one of ordinary skill in the art to which this invention belongs. In case of conflict, the present specification, including the definitions herein, will control.

The terms “complementary” and “complementarily”, as used herein, refer to numbers that sum to 100%.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The transitional phrase “consisting of” excludes any element, step, or ingredient not specified in the claim, closing the claim to the inclusion of materials other than those recited except for impurities ordinarily associated therewith. When the phrase “consists of” appears in a clause of the body of a claim, rather than immediately following the preamble, it limits only the element set forth in that clause; other elements are not excluded from the claim as a whole.

The transitional phrase “consisting essentially of” limits the scope of a claim to the specified materials or steps and those that do not materially affect the basic and novel characteristic(s) of the claimed invention. A ‘consisting essentially of’ claim occupies a middle ground between closed claims that are written in a ‘consisting of’ format and fully open claims that are drafted in a ‘comprising’ format. Optional additives as defined herein, at a level that is appropriate for such additives, and minor impurities are not excluded from a composition by the term “consisting essentially of”.

When a composition, a process, a structure, or a portion of a composition, a process, or a structure, is described herein using an open-ended term such as “comprising,” unless otherwise stated the description also includes an embodiment that “consists essentially of” or “consists of” the elements of the composition, the process, the structure, or the portion of the composition, the process, or the structure.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

The term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

The term “or”, as used herein, is inclusive; that is, the phrase “A or B” means “A, B, or both A and B”. Exclusive “or” is designated herein by terms such as “either A or B” and “one of A or B”, for example.

In addition, the ranges set forth herein include their endpoints unless expressly stated otherwise. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately described. The scope of the invention is not limited to the specific values recited when defining a range.

When materials, methods, or machinery are described herein with the term “known to those of skill in the art”, “conventional” or a synonymous word or phrase, the term signifies that materials, methods, and machinery that are conventional at the time of filing the present application are encompassed by this description. Also encompassed are materials, methods, and machinery that are not presently conventional, but that will have become recognized in the art as suitable for a similar purpose.

Unless stated otherwise, all percentages, parts, ratios, and like amounts, are defined by weight.

The term “ionomer” as used herein refers to a polymer that comprises ionic groups that are carboxylates associated with cations, for example, ammonium carboxylates, alkali metal carboxylates, alkaline earth carboxylates, transition metal carboxylates and/or mixtures of such carboxylates. Such polymers are generally produced by partially or fully neutralizing the carboxylic acid groups of precursor or parent polymers that are acid copolymers, for example by reaction with a base. An example of an ionomer described herein is a zinc/sodium mixed ionomer, for example a copolymer of ethylene and methacrylic acid wherein all or a portion of the carboxylic acid groups of the copolymerized methacrylic acid units are in the form of zinc carboxylates and sodium carboxylates.

Finally, the term “solar cell”, as used herein, refers to any article that is capable of converting light into electrical energy; and the term “light concentrating article”, as used herein, refers to any optical system that is capable of capturing the light shining on a larger area and casting, directing, refracting or focussing the light onto a smaller area.

Provided herein are processes for manufacturing light concentrating articles for use in concentrator solar cell modules. The light concentrating articles, which are capable of concentrating about 1.02 to about 2000 sun equivalents of solar energy onto a solar cell, comprise or are made from thermoplastic compositions, preferably ionomer compositions. The processes include an injection molding process, an injection overmolding process, an extrusion process, a cast film or sheet process, a blown film or sheet process, a vacuum forming process, a compression molding process, a transfer molding process, or a profile extrusion process. Secondary forming processes, such as bending, stamping, embossing, machining, laminating, adhering, metallizing, and the like may also be used in forming the light concentrating articles. It may be necessary or desirable to use two or more of the processes or secondary processes to form the light concentrating article.

The concentrator solar cell modules comprise one or more light concentrating articles and one or a plurality of solar cells positioned in such a way that light is concentrated on the solar cell(s) by the light concentrating article(s). The light concentrating articles comprise a thermoplastic composition, preferably an ionomer composition. The solar cells may be part of a simpler solar cell module that is incorporated into the concentrator solar cell module. Suitable solar cell modules and concentrator solar cell modules are described in the Handbook of Photovoltaic Science and Engineering, cited above. Preferred solar cells are described in U.S. patent application Ser. No. 12/626,046, filed on Nov. 25, 2009.

Light concentrating articles suitable for use in the concentrator solar cell modules include any optical article that is capable of providing a solar concentration of about 1.02 or 1.04 to about 2000, preferably about 1.4, 1.45 or 1.5 to about 1700 suns. In addition, the light concentrating article comprises a thermoplastic composition or, preferably, an ionomer composition such as the one described below. More specifically, one or more parts of the light concentrating article, or the light concentrating article as whole, comprises or is prepared from the thermoplastic composition. One preferred light concentrating article is capable of providing a solar concentration of about 2 to about 10 suns and is useful in a low efficiency concentrator solar cell module. Another preferred light concentrating article is capable of providing a solar concentration of about 200 suns or higher, or about 500 to about 1000 suns, and is useful in a high efficiency concentrator solar cell module.

The light concentrating articles may have any suitable form. For example, the light concentrating articles may be in the form of a reflective optical system, or a refractive optical system, or an optical system that acts by both reflection and refraction. Alternatively, the light concentrating article may be in the form of a reflective optical system comprising a reflective mirror, a reflective paraboloid, a reflective dish, or a linear parabolic trough. In another configuration, the light concentrating article may be in the form of a refractive optical system comprising a refractive lens or a secondary light concentrating article, such as a dichroic filter.

The refractive lens may be derived from imaging optics or non-imaging optics. Further, the refractive lens may be a shaped incident encapsulant layer, a cover slide comprising a converging lens, a cover glass comprising a converging lens, a converging lens, a simple lens, a complex lens, a biconvex lens, a plano-convex lens, a positive meniscus lens, a plano-concave lens, an aspheric lens, an inflatable lens, a Fresnel lens, a linear Fresnel lens, a linear arched Fresnel lens, a point focus Fresnel lens, a segmented Fresnel lens, or a combination of two or more of any of these configurations.

Moreover, all or a portion of the light concentrating article may further comprise an antireflective coating. In particular, the surface of the light concentrating article may be partially or completely coated with an antireflective coating. It may be particularly desirable to provide refractive lenses with an antireflective coating. Suitable antireflective coatings may be formed of a material selected from metal fluorides, such as CaF₂, AlF₃, or MgF₂; fluoropolymers; fluoroelastomers, and mixtures of two or more of these materials. Examples of suitable antireflective coatings are described in U.S. Provisional Appln. Nos. 60/991,294, filed on Nov. 30, 2007; 61/015,063, -074 and -080, filed on Dec. 19, 2007; U.S. patent application Ser. Nos. 11/888,382 and -383, filed on Aug. 1, 2007; in other U.S. patent applications filed by Jose Manuel Rodriguez-Parada inter alia or Kostantinos Kourtakis inter alia, including U.S. Provisional Appln. Nos. 60/873,861, filed on Dec. 8, 2006; and 61/139,657 and -661, filed on Dec. 22, 2008; in the U.S. and international applications that claim priority to the above-mentioned applications; and in the references cited in the above-mentioned applications.

Also preferably, reflective optical systems may be metallized, polished, or treated by other means to enhance the amount of light that is reflected onto the solar cells. Suitable conditions and apparatus for metallizing objects comprising ionomer compositions are described in U.S. patent application Ser. Nos. 12/077,307, filed on Mar. 17, 2008, and 12/511,678, filed on Jul. 29, 2009.

Examples of suitable and preferred light concentrating articles are described in U.S. patent application Ser. No. 12/626,046, cited above.

The light concentrating article comprises a thermoplastic composition, which, in turn, comprises a thermoplastic polymer. Suitable thermoplastic polymers include, without limitation, polyesters such as poly(ethylene terephthalate), polyacrylates, polycarbonate, polypropylene, polyethylene, cyclic polyolefins, norbornene polymers, polystyrene, syndiotactic polystyrene, styrene-acrylate copolymers, acrylonitrile-styrene copolymers, poly(ethylene naphthalate), polyethersulfone, polysulfone, polyamides, including nylons, poly(urethanes), acrylics such as poly(methyl methacrylate), cellulose acetates, cellulose triacetates, vinyl chloride polymers, polyvinyl fluoride, polyvinylidene fluoride, poly(ethylene-co-vinyl acetate); ethyl acrylic acetate (EM); ethyl methacrylate (EMAC); poly (ethylene-co-acrylates), metallocene-catalyzed polyethylene; plasticized poly(vinyl chloride); ISD resins; polyurethane; acoustically modified poly(vinyl chloride), an example of which is commercially available from the Sekisui Company; plasticized poly(vinyl butyral); acoustically modified poly(vinyl butyral); silicone rubbers; and the like and copolymers thereof and combinations thereof.

Preferably, the light concentrating article comprises an ionomer composition, which, in turn, comprises an ionomer. Ionomers are thermoplastic ionic copolymers that are known for use as solar cell encapsulant materials. See, for example, U.S. Pat. Nos. 5,476,553; 5,478,402; 5,733,382; 5,741,370; 5,762,720; 5,986,203; 6,114,046; 6,187,448; 6,353,042; 6,320,116; and 6,660,930; and U.S. Patent Appln. Publn. Nos. 2003/0000568; 2005/0279401; 2008/0017241; 2008/0023063; 2008/0023064; and 2008/0099064. In addition to their controllable clarity and ease of processing, ionomers have stable mechanical properties that render them suitable for use in light concentrating articles. Suitable and preferred ionomers are described at length in U.S. patent application Ser. No. 12/626,046, cited above.

Briefly, however, most thermoplastic materials are characterized by a correlation between peak melting temperature (Tm), as measured by differential scanning calorimetry (DSC), and creep. Therefore, materials having a Tm less than about 60° C. have not been considered suitable candidates for use in light concentrating articles in solar cell modules. The assumption is that materials having a relatively low Tm will also be characterized by a low temperature of creep onset and a high level of creep. These properties will lead to unacceptably large deformation over the time period and under the conditions in which the solar cell module will be used. The deformed light concentrating articles will not function as efficiently, and therefore the solar cells will produce less electricity.

Surprisingly, this correlation does not apply with the same severity to the preferred ionomers. In fact, preferred ionomers are characterized by a significant, sign-inverted difference between the Tm and the temperature of creep onset. Advantageously, the temperature of onset of the ionomers' creep is higher than the peak melting temperature. In preferred ionomers, the temperature onset of creep is at least 5° C., at least 8° C. or at least 10° C. higher than the peak melting temperature. Thus, counterintuitively, the preferred ionomers have low levels of creep at temperatures that are higher than their Tm. These creep levels and onset temperatures place the preferred ionomers squarely in the range of materials that are suitable for long-term use in light concentrating solar cell modules.

Suitable α-olefin comonomers; suitable α,β-ethylenically unsaturated carboxylic acid comonomers; and suitable optional additional comonomer(s) are described at length in U.S. patent application Ser. No. 12/626,046, cited above. Likewise, suitable and preferred physical properties of the ionomers are described at length in the above-cited application.

To summarize, however, suitable ionomers are neutralized derivatives of a precursor acid copolymer comprising copolymerized units of an α-olefin having 2 to 10 carbon atoms and copolymerized units of an α,β-ethylenically unsaturated carboxylic acid having 3 to 8 carbons. The ionomers may comprise 40 wt % to 90 wt % of the copolymerized α-olefin and 10 wt % to 60 wt % of the copolymerized carboxylic acid, based on the total weight of the precursor acid copolymer. Preferably, the ionomers comprise 65 to 90 wt % or 70 to 85 wt % of the copolymerized α-olefin and 10 to 35 wt % or 15 to 30 wt % of the copolymerized carboxylic acid, and more preferably 75% to 80% of the copolymerized α-olefin and 20% to 25% of the copolymerized carboxylic acid. Preferably, the α-olefin is ethylene and the α,β-ethylenically unsaturated carboxylic acid is selected from acrylic acids, methacrylic acids, and mixtures of two or more thereof.

The precursor acid copolymers may further comprise copolymerized units of one or more other comonomer(s), such as unsaturated carboxylic acids having 2 to 10, or preferably 3 to 8 carbons, or derivatives thereof. Suitable acid derivatives include acid anhydrides, amides, and esters. Some suitable precursor acid copolymers further comprise an ester of the unsaturated carboxylic acid. Examples of suitable esters of unsaturated carboxylic acids include, but are not limited to, those that are set forth in U.S. patent application Ser. No. 12/610,678, filed on Nov. 2, 2009). Examples of preferred comonomers include, but are not limited to, methyl acrylates, methyl methacrylates, butyl acrylates, butyl methacrylates, glycidyl methacrylates, vinyl acetates, and mixtures of two or more thereof. Preferably, however, the precursor acid copolymer does not incorporate other comonomers.

When a light concentrating article having low haze is desired, the precursor acid copolymer may have a melt flow rate (MFR) of about 1 to about 1000 g/10 min, preferably about 20 to about 900 g/10 min, more preferably about 60 to about 700 g/10 min, yet more preferably of about 100 to about 500 g/10 min, yet more preferably of about 150 to about 300 g/10 min, and most preferably of about 200 to about 250 g/10 min, as determined in accordance with ASTM method D1238 at 190° C. and 2.16 kg. When a measurable or significant level of haze is tolerable, however, the precursor acid copolymer preferably has a melt flow rate of about 60 g/10 min or less, more preferably about 45 g/10 min or less, yet more preferably about 30 g/10 min or less, or most preferably about 25 g/10 min or less, as measured by ASTM method D1238 at 190° C. and 2.16 kg. Again, in general, lower melt indices will favor lower creep.

The precursor acid copolymers may be polymerized as described in U.S. Pat. No. 3,404,134; 5,028,674; 6,500,888; or 6,518,365, for example. They may be neutralized by procedures such as those described in U.S. Pat. Nos. 3,404,134 and 6,518,365.

To obtain the ionomer useful in the ionomer composition of the light concentrating article, the precursor acid copolymer is preferably neutralized to a level of about 5% to about 90%, or preferably about 10% to about 60%, or more preferably about 20% to about 55%, or yet more preferably about 35% to about 55%, or most preferably about 40% to about 55%, based on the total carboxylic acid content of the precursor acid copolymers as calculated or measured for the non-neutralized precursor acid copolymers. The more preferable and most preferable neutralization ranges make it possible to obtain an ionomer sheet or molded article having one or more desirable properties such as low haze, high clarity, sufficient impact resistance, and good processability. Lower creep levels, however, are generally favored by higher neutralization levels.

Any cation that is stable under the conditions of polymer processing and solar cell fabrication is suitable for use in the ionomers. Ammonium cations are suitable, for example. Metal ions are preferred cations. The metal ions may be monovalent, divalent, trivalent, multivalent, or mixtures thereof. When multivalent metal ions are used, complexing agents such as stearate, oleate, salicylate, and phenolate radicals may be included, as described in U.S. Pat. No. 3,404,134. The metal ions are preferably monovalent or divalent metal ions. In one preferred ionomer, the metal ions are selected from sodium, lithium, magnesium, zinc, potassium and mixtures thereof. In another preferred ionomer, the metal ions are selected from sodium, zinc and mixtures thereof. Zinc is a preferred cation when resistance to the incursion of moisture is required.

The ionomer used in the light concentrating article may have a MFR of 0.75 to about 20 g/10 min, preferably about 1 to about 10 g/10 min, yet more preferably about 1.5 to about 5 g/10 min, and most preferably about 2 to about 4 g/10 min, as determined in accordance with ASTM method D1238 at 190° C. and 2.16 kg. Surprisingly, some of these ionomers have lower haze and higher clarity in combination with lower moisture absorption then those found within the art at equal melt viscosity, as measured, for example, by MFR. Generally, lower creep is promoted by lower melt indices.

In one preferred light concentrating article, the ionomer(s) used in the ionomer composition are selected from among the low haze, high clarity ionomers described in U.S. patent application Ser. Nos. 12/610,678, cited above, or 12/610,881, filed on Nov. 2, 2009.

Alternatively, it may be advantageous for the light concentrating article to have a measurable level of haze. For example, a Fresnel lens having an appreciable level of haze will cast light on the solar cells more evenly that a Fresnel lens having an insignificant level of haze. In general, ionomers that include lower levels of copolymerized acid, or that include optional copolymerized esters, or that are synthesized under multiphase reaction conditions (see U.S. patent application Ser. No. 12/610,678, cited above) tend to have appreciable levels of haze. In addition, other strategies for increasing haze include cooling the ionomer composition slowly to promote crystallinity in the ionomer's poly(ethylene) segments; neutralizing the copolymerized acid residues to a lesser extent; including other polymers that have higher haze in the ionomer composition; and adding filler to the ionomer composition.

Suitable ionomers are commercially available from E.I. du Pont de Nemours and Company of Wilmington, Del. (hereinafter “DuPont”) under the Surlyn® trademark, under the SentryGlas® trademark, or through the PV Series, such as PV5300.

The thermoplastic compositions may further include one or more additives. Suitable additives, levels of additives, and methods of incorporating the additives into the thermoplastic compositions are as set forth in U.S. patent application Ser. No. 12/626,046, cited above, with respect to the ionomer compositions. Briefly, however, the thermoplastic compositions may optionally include initiators such as dibutyltin dilaurate, which may be present especially in the ionomeric compositions at a level of about 0.01 to about 0.05 wt %, based on the total weight of the ionomer composition.

The ionomer compositions may further contain melt flow reducing additives such as organic peroxides; and silane additives that promote adhesion and cross-linking. In this connection, and as discussed above, dimensional stability is an important property of the components of a solar cell. Therefore, in some ionomer compositions, it is preferred to use a crosslinking agent to increase the dimensional stability of the light concentrating article. For the sake of process simplification and ease, however, it may be preferred that cross-linking additives be omitted from the ionomer compositions.

Other additives of note that are not particular to ionomer compositions include thermal stabilizers, UV absorbers and hindered amine light stabilizers. Suitable and preferred additives, levels of the additives in ionomer compositions, and methods of incorporating the additives into the compositions are described at length in U.S. patent application Ser. No. 12/610,678, cited above. The additive levels and methods for incorporation described therein apply to thermoplastic compositions in general.

The thermoplastic composition may also contain one or more other additives known in the art. The additives may include, but are not limited to, processing aids, flow enhancing additives, lubricants, pigments, dyes, flame retardants, impact modifiers, nucleating agents, anti-blocking agents such as silica, UV stabilizers, dispersants, surfactants, chelating agents, other coupling agents, and reinforcement additives, such as glass fiber, fillers, and the like, and mixtures or combinations of two or more conventional additives. These additives are described in the Kirk Othmer Encyclopedia of Chemical Technology, 5^{th} Edition, John Wiley & Sons (New Jersey, 2004), for example. Moreover, the optional incorporation of such conventional ingredients into the compositions can be carried out by any known process. This incorporation can be carried out, for example, by dry blending, by extruding a mixture of the various constituents, by the masterbatch technique, or the like. See, again, the Kirk Othmer Encyclopedia.

The light concentrating article may be produced by any suitable process. For example, it may be formed by an injection molding process, an injection overmolding process, an extrusion process, a cast film or sheet process, a blown film or sheet process, a blow molding process, a vacuum forming process, a compression molding process, a transfer molding process, or a profile extrusion process. Secondary forming processes, such as bending, stamping or embossing, machining, laminating, adhering, metallizing, and the like may also be used in forming the light concentrating articles. It may be necessary or desirable to use two or more of the processes or secondary processes to form the light concentrating article. General information regarding these methods may be found in the Kirk Othmer Encyclopedia, in the Modern Plastics Encyclopedia, McGraw-Hill (New York, 1995) or in the Wiley Encyclopedia of Packaging Technology, 2d edition, A. L. Brody and K. S. Marsh, Eds., Wiley-Interscience (Hoboken, 1997).

In particular, however, the preferred processes include a melt processing step. In the melt processing step, the thermoplastic polymer is heated above its melting temperature. The optional additives may be added to the thermoplastic polymer before it is melted, in a “salt and pepper blend”, for example. Alternatively, the optional additives may be added to the polymer melt. Suitable melt processing conditions, such as temperatures and pressures, depend largely on the identity of the thermoplastic polymer, although they may be affected by the selection of optional additives and levels. This information is available in the reference texts cited above, for example. For ionomer compositions in a typical injection molding process, the melt temperature may be in the range of 100° C. to 300° C. and the injection pressure may be in the range of 20 to 180 MPa. Extrusion pressures are generally closer to the lower limit of this range.

The thermoplastic composition is then shaped, either into the final form of the light concentrating article or into an intermediate form for further shaping. Suitable methods for forming the melted thermoplastic composition directly into its final form include injection molding, vacuum forming, and compression molding. In these processes, the molten thermoplastic composition is pumped or drawn directly into a mold whose form is the inverse of the form of the light concentrating article.

Also suitable for forming the melted thermoplastic composition directly into its final form is extrusion casting onto a textured surface. The molten thermoplastic composition may be cast onto a textured surface and then removed, producing a sheet that is patterned with the inverse texture. The inverse-textured sheet is the light concentrating article, or a portion of the sheet is used as the light concentrating article. Alternatively, the extruded sheet and the textured surface may remain together, for example to form a reflective light concentrating article, when their indices of refraction differ by a substantial amount. Optionally, however, the inverse-textured sheet may be further processed, as by trimming, metallization, or adhering, as to a substrate, to become the light concentrating article.

In a profile extrusion process, a shaped die forms a continuous sheet whose cross-section may define a concave lens, a convex lens, or a segmented lens. In general, the profile of the sheet is constant in the machine direction, although it may be changed during a run by adjusting the die gap, or by varying the speed of the extrusion or the take-up rolls. Again, the profile-extruded sheet may be the light concentrating article, or it may be further processed to become the light concentrating article.

Some preferred processes, however, also include the step of forming the thermoplastic composition into an intermediate form, such as a blank, a parison, a tube, a film or a sheet. Preferred processes for forming a tube include extrusion, while parisons may also be formed by extrusion followed by cutting and sealing. Tubes and parisons are preferably formed further by blow molding processes, in which the tube or parison is heated to malleability, placed inside a mold, and then filled with air from the inside so that the tube or parison expands to contact the walls of the mold.

Preferred processes for forming the thermoplastic composition into a film or sheet include casting, extrusion and extrusion casting. Again, the thickness of the sheet or film depends on the optical properties of the thermoplastic material, on the design requirements of the concentrator solar cell module, and on the additional processing steps. In particular, a film without a supporting substrate (polyester film, for example) may need to be thicker if it will be used in a roll-to-roll embossing procedure than if it will be used in a lamination and embossing process. In a roll-to-roll embossing process, the sheet or film is pressed against a patterned sheet or film in a nip, optionally a heated nip, to impart the inverse pattern to the sheet that will become the light concentrating article.

Preferred processes for forming sheets and films into light concentrating articles include stamping or embossing combined with lamination to form the light concentrating articles in a one-step or two-step procedure. For example, in a two step process, an ionomer sheet may be laminated to a glass substrate by processes that have been described elsewhere. See, e.g., U.S. Pat. No. 7,641,965, issued to Bennison et al. It is to be noted that an adhesive is generally not required to cause the ionomer to adhere to the glass, although one may optionally be used. Aminosilanes are suitable reactive coupling agents for adhesion promotion. They may be added to the ionomer composition or coated on the glass or on the ionomer. Subsequently to the lamination, the desired pattern may be stamped or embossed onto the ionomer sheet. In the case of a sheet comprising an ionomer composition, temperatures of about 135° C. and pressures of about 5 MPa or less may be applied for times of about 10 minutes or less. The times may be decreased by the application of radiofrequency heating or inductive heating, which may be applied to the nickel or aluminum platen that typically bears the embossing pattern.

Alternatively, the thermoplastic film or sheet may be laminated to the substrate and embossed with a pattern in a one step process. Specifically, an ionomer sheet may be stacked with a substrate and a patterned template to form a pre-lamination assembly. Apparently, the patterned side of the template will be stacked adjacent to the ionomer sheet. The pre-lamination assembly may then be embossed under conditions that are similar to the lamination conditions described above (time, temperature and pressure) so that the lamination and embossing are accomplished simultaneously.

Finally, when a pattern is pressed or embossed onto the light concentrating article, the original from which the pattern is pressed preferably has a non-stick surface. For example, the embossing plate may have a surface coated with a polyester or polycarbonate. Alternatively, when the intermediate article to be embossed is coated with a fluoropolymer-based antireflective coating, as described above, the coating also functions as a non-stick surface.

The following examples are provided to describe the invention in further detail. These examples, which set forth a preferred mode presently contemplated for carrying out the invention, are intended to illustrate and not to limit the invention.

### EXAMPLES

Slides of float glass (Krystal Klear Solar Glass™ from AFG Industries Inc., Kingsport, Tenn.) measuring 2 in×2 in (5.1 cm×5.1 cm) were immersed for five minutes in an ethanolic solution of 3-aminopropyl-trimethoxysilane (about 5 drops in 100 g of 95% ethanol, resulting in an aminosilane concentration of approximately 0.01%). The slides were removed from the solution, rinsed with isopropanol, and dried under a flow of high pressure nitrogen gas. The treated slides were further dried in an oven at 100° C. for 30 minutes.

Uncoated films were prepared from sheets of Surlyn® 9120, available from DuPont. The Surlyn® sheets were dried under vacuum for 48 hours at 50° C., then calendered to a thickness of 5 mil (0.127 mm) using a Model XRL-120 Hot Roll Laminator (Western Magnum Corporation, El Segundo, Calif.) at 155° C. and 19 psi (0.13 MPa). The calendered films were cut into squares measuring 2 in by 2 in (5.1 cm×5.1 cm).

Coated films were prepared by drying the Surlyn® 9120 sheets at 40° C. under vacuum for 2 weeks, then calendering them to a thickness of 5 mils (0.127 mm) by the same procedure used for the uncoated films. A fluoropolymer-based antireflective coating solution was prepared by dissolving 2 g Viton® GF-2005 fluoroelastomer (DuPont), 0.2 g Irgacure®-651 (Ciba Specialty Chemicals) and 0.2 g triallyl isocyanurate (Aldrich) in 32 g propyl acetate, then filtering the solution through a 0.45 μm Teflon® PTFE membrane filter. The calendered Surlyn® films were coated with the anti-reflective coating solution a using a Mini-Labo coater (Yasui Seiki Co., Bloomington, Ind.) under the following conditions: #200 MG roll @ 6.5 rpm, line speed=0.5 m/min, dryer off and no airflow. The coatings were uniform in thickness as determined by spectral reflectance measurements using a thin film analyzer (Model F20-EXR from Filmetrics, Inc., San Diego, Calif.; Rmin=640 to 650 nm).

The coated films were cured immediately after coating. First, a film measuring 4 in×24 in (10.2 cm×61.2 cm) was placed on an aluminum sample holder that had been warmed on a hotplate at 75° C. This assembly was passed twice through a Model SB614 Benchtop Conveyor UV curing unit (Fusion UV Systems, Gaithersburg, Md.) at a speed of 0.7 mm/min. The frequencies and intensities of the radiation are set forth in Table 1. The cured films were cut into squares measuring 2 in by 2 in (5.1 cm×5.1 cm) and stored under ambient conditions.

TABLE 1

| UV-A | | UV-B | | UV-C | | UV-V | |
|---|---|---|---|---|---|---|---|
| J/cm² | W/cm² | J/cm² | W/cm² | J/cm² | W/cm² | J/cm² | W/cm² |
| 0.561 | 0.200 | 0.370 | 0.128 | 0.070 | 0.022 | 0.269 | 0.1 |

Pre-lamination assemblies were prepared by stacking the Surlyn® 9120 films against the tin side of the treated float glass slides. The uncoated side of the coated Surlyn® films was in contact with the glass slide. Each pre-lamination assembly was placed in a sample holder assembly under vacuum. The loaded sample holder assembly was inserted into a Carver press that was heated to 150° C. Once the temperature of the press re-stabilized at 150° C., pressure (less than 1000 psi (6.89 MPa)) was applied to the sample holder assembly and held for 15 minutes. The heating was discontinued and the press was cooled with water. The sample assembly was removed from the press after it had cooled to 60° C.

The Surlyn®/glass laminates were embossed with a Fresnel lens pattern. An embossing template was stacked against the Surlyn® layer, and this assembly was processed in a Carver press according to the procedure outlined above for lamination, except that a pressure of less than 500 psi (3.45 MPa) was applied for 5 min. The templates and temperatures used for embossing each Example are set forth in Table 2.

TABLE 2

| Example | Coated (C) or | Embossing | Embossing |
|---|---|---|---|
| No. | Uncoated (U) | Template* | Temperature, C. ° |
| E1 | U | AB | 90 |
| E2 | U | FL | 90 |
| E3 | U | FL | 95 |
| E4 | U | FL | 100 |
| E5 | C | AB | 100 |
| E6 | C | FL | 90 |
| E7 | C | FL | 95 |

*AB is an aluminum block machined with a pattern consisting of linear triangular grooves with alternating peak heights of 60 and 100 micrometers and bases that are 500 micrometers in width. FL is a commercially available plastic pocket-sized Fresnel lens.

The surface patterns of Example Nos. E1, E2, E4 and E5 were measured as profile scans using a DekTak profilometer (Veeco Instruments, Inc., Plainview, N.Y.). The surface patterns of the Fresnel lens (before and after embossing) and of the aluminum block were also measured. The conditions of the profile scans were: stylus type: radius, 12.5 μm; scan length: 5000 μm; resolution: 1.111 μm/sample; stylus force: 3 mg; scan length: 5000 μm; samples: 4500; duration: 15 sec; measurement range: 2620 kÅ.

The profile measurements revealed that the inverse structure of the aluminum mold was replicated with good precision on the Surlyn®/glass laminated samples. The inverse pattern of the Fresnel lens, however, was not replicated with the same degree of precision. Moreover, distortion is observed in the surface pattern of the Fresnel lens after embossing. It is hypothesized that the Fresnel lens was made of poly(methyl methacrylate) or another material that might be subject to distortion under the embossing conditions.

Confocal microscopy further confirmed the precision with which the Fresnel lens pattern was transferred in Example E2.

In summary, the Examples demonstrate that micro-patterns, including optical Fresnel patterns, can be accurately embossed onto Surlyn®/glass laminates at relatively low pressures and temperatures.

While certain of the preferred embodiments of the present invention have been described and specifically exemplified above, it is not intended that the invention be limited to such embodiments. Various modifications may be made without departing from the scope and spirit of the present invention, as set forth in the following claims.

What is claimed is:

1. A method of making a light concentrating article, wherein:
(A) the light concentrating article is capable of concentrating about 1.02 to about 2000 suns of solar energy onto the solar cells;
(B) the at least one light concentrating article comprises an ionomer composition, and the ionomer composition comprises or is prepared from an ionomer; and
(C) the ionomer has a temperature onset of creep and a peak melting temperature; and the temperature onset of creep is at least 5° C. higher than the peak melting temperature;
said method selected from the group consisting of an injection molding process, an injection overmolding process, an extrusion process, a cast film or sheet process, a blown film or sheet process, a blow molding process, a vacuum forming process, a compression molding process, a transfer molding process, or a profile extrusion process.

2. The method of claim 1, wherein the temperature onset of creep is at least 8° C. higher than the peak melting temperature.

3. The method of claim 1, further comprising one or more secondary forming processes selected from the group consisting of bending, stamping, embossing, machining, laminating, adhering, and metallizing.

4. The method of claim 1, wherein the thermoplastic composition further comprises one or more thermoplastic polymers selected from the group consisting of poly(ethylene terephthalate)s, polycarbonates, polypropylenes, polyethylenes, cyclic polyolefins, norbornene polymers, polystyrenes, styrene-acrylate copolymers, acrylonitrile-styrene copolymers, poly(ethylene naphthalate)s, polyethersulfones, polysulfones, polyamides, poly(urethanes), acrylics, cellulose acetates, cellulose triacetates, vinyl chloride polymers, polyvinyl fluorides, polyvinylidene fluorides, poly(ethylene-co-vinyl acetate)s, ethyl acrylic acetates, ethyl methacrylates, poly (ethylene-co-acrylate)s, poly(vinyl chloride)s, ISD resins, silicone rubbers, and poly(vinyl butyral)s.

5. The method of claim 1, comprising the steps of extruding the thermoplastic composition into a sheet, laminating the sheet to a substrate, and stamping or embossing a pattern onto the laminated sheet to form the light concentrating article.

6. The method of claim 1, comprising the steps of extruding the thermoplastic composition into a sheet, stacking the sheet with a substrate, and stamping or embossing a pattern onto the sheet to form a patterned laminate that is the light concentrating article.

7. The method of claim 1, wherein the light concentrating article is a refractive lens, and further comprising the step of coating at least a portion of the refractive lens with an antireflective coating.

8. The method of claim 7, wherein the antireflective coating comprises a material selected from CaF₂, AlF₃, MgF₂, a fluoropolymer, a fluoroelastomer, and mixtures of two or three of CaF₂, AlF₃, MgF₂, the fluoropolymer, and the fluoroelastomer.

9. A concentrator solar cell module comprising a light concentrating article made by the method of claim 1, wherein the light concentrating article is part of a reflective optical system, a refractive optical system, or both a reflective and a refractive optical system in the solar cell module.

10. The concentrator solar cell module of claim 9, wherein the reflective optical system is selected from the group consisting of a reflective mirror, a reflective paraboloid, a reflective dish, and a linear parabolic trough.

11. The concentrator solar cell module of claim 9, wherein the refractive optical system is selected from the group consisting of a refractive lens and a dichroic filter.

12. The concentrator solar cell module of claim 9, wherein the refractive lens is derived from imaging optics; or wherein the refractive lens is derived from non-imaging optics.

13. The concentrator solar cell module of claim 11, wherein the refractive lens is selected from the group consisting of a shaped incident encapsulant layer, a cover slide comprising a converging lens, a cover glass comprising a converging lens, a converging lens, a simple lens, a complex lens, a biconvex lens, a plano-convex lens, a positive meniscus lens, a plano-concave lens, an aspheric lens, an inflatable lens, a Fresnel lens, a linear Fresnel lens, a linear arched Fresnel lens, a point focus Fresnel lens, a segmented Fresnel lens, and a combination of two or more of any of these lenses.

14. A concentrator solar cell module comprising one or a plurality of solar cells and at least one light concentrating article made by the process of claim 1, wherein the ionomer comprises carboxylate groups and cations and is the product of a neutralization of a precursor α-olefin carboxylic acid copolymer; the precursor α-olefin carboxylic acid copolymer comprises (i) copolymerized units of an α-olefin having 2 to 10 carbons and (ii) about 18 to about 30 wt % of copolymerized units of an α,β-ethylenically unsaturated carboxylic acid having 3 to 8 carbons, based on the total weight of the α-olefin carboxylic acid copolymer; and about 5% to about 90% of the total content of the carboxylic acid groups present in the precursor α-olefin carboxylic acid copolymer are neutralized to form the ionomer.

15. The concentrator solar cell module of claim 14, wherein the precursor α-olefin carboxylic acid copolymer comprises about 20 to about 25 wt % of copolymerized units of the α,β-ethylenically unsaturated carboxylic acid.

16. The concentrator solar cell module of claim 14, wherein about 20% to about 55% of the total content of the carboxylic acid groups present in the precursor α-olefin carboxylic acid copolymer are neutralized.

17. The concentrator solar cell module of claim 14, wherein the ionomer has a melt flow rate of about 0.75 to about 20 g/10 min and the precursor α-olefin carboxylic acid copolymer has a melt flow rate of about 1 to about 1000 g/10 min, as determined in accordance with ASTM D1238 at 190° C. and under a weight of 2.16 kg.

18. The concentrator solar cell module of claim 14, wherein the cations include ions of sodium, ions of zinc, or ions of both sodium and zinc.

19. The concentrator solar cell module of claim 18, wherein the cations comprise about 55 to about 70 equiv % of sodium ions and, complementarily, about 30 to about 45 equiv % of zinc ions.

20. The concentrator solar cell module of claim 18, wherein the cations consist essentially of zinc ions.
